(19) United States
(12) Patent Application Publication
(10) Pub. No.: US 2012/0199822 A1
(43) Pub. Date: Aug. 9, 2012

(54) ORGANIC TRANSISTOR

(75) Inventors: Masakazu Kamura, Osaka (JP); Shigeru Aomori, Osaka (JP); Yasutaka Kuzumoto, Osaka (JP)

(73) Assignee: SHARP KABUSHIKI KAISHA, Osaka-shi ,Osaka (JP)

(21) Appl. No.: 13/501,079

(22) PCT Filed: Oct. 19, 2010
(86) PCT No.: PCT/JP2010/068368

§ 371 Date: Apr. 9, 2012

(30) Foreign Application Priority Data
Nov. 25, 2009 (JP) 2009-267855

(51) Int. Cl. H01L 51/10

(52) U.S. Cl. 257/40; 257/E51.006

(57) ABSTRACT

An organic transistor (1) includes: an injection improvement layer (40) between a source electrode (14) and an organic semiconductor layer (16); and an extraction improvement layer (50) between a drain electrode (15) and the organic semiconductor layer (16). An electric dipole moment of a material or molecules of the extraction improvement layer (50) has an absolute value lager than that of the injection improvement layer (40). Accordingly, all carriers in the organic semiconductor, which are injected from the source electrode during operation of the transistor, can be drawn out (extracted) into the drain electrode. This reduce contact resistances. Therefore, provided are the organic transistor that reduces a contact resistance between the organic semiconductor layer and the source electrode and a contact resistance between the organic semiconductor layer and the drain electrode and attains to demonstrate stable operation, and a method for fabricating the organic transistor.

### TECHNICAL FIELD

The present invention relates to a so-called organic transistor which is a field effect transistor including a semiconductor layer made from an organic semiconductor material and a method for fabricating the organic transistor.

### BACKGROUND ART

Devices of a so-called organic transistor (which is a field effect transistor including a semiconductor layer made from an organic semiconductor material) can be provided on a large-area substrate or a plastic substrate more easily than those of an inorganic semiconductor such as silicon. This is because the devices of the organic transistor can be formed without being subjected to a vacuum process or a thermal process which is performed in a state of a temperature of 200° C. or more, and can be formed by means of a printing technique such as an inkjet method or screen printing, or a solution process such as spin coating or a cast method. Therefore the organic transistor is expected to be provided to a flexible display and an electronic tag. However, the organic transistor is still inferior to an inorganic semiconductor device in view of carrier mobility of the organic semiconductor material and electrical properties such as a contact resistance between an organic semiconductor layer (organic semiconductor material) and a source electrode, and a contact resistance between the organic semiconductor layer and a drain electrode. Accordingly, an object of the organic transistor is to improve the carrier mobility, the electrical properties, etc.

In particular, reducing (i) the contact resistance between the organic semiconductor layer and the source electrode and (ii) the contact resistance between the organic semiconductor layer and the drain electrode improves transistor properties, such as improvement in the carrier mobility, increase in ON-current, and reduction in threshold voltage. The reason why the transistor properties are improved by reducing the contact resistances is as follows: unlike the inorganic semiconductor layer, the organic semiconductor layer does not contain a carrier in its material and a carrier cannot be doped to the organic semiconductor layer, so that the carrier is supplied (injected) to the organic semiconductor layer from the source electrode, and hence the contact resistance between the source electrode and the organic semiconductor layer greatly influences the transistor properties. Further, the carrier thus injected needs to be efficiently extracted to the drain electrode through the organic semiconductor layer. Therefore, reducing the contact resistance between the drain electrode and the organic semiconductor layer is also an important object.

A reason for causing the contact resistances is an injection barrier which is generated by an energy gap existing between (i) a work function of a metal used in the source and drain electrodes and (ii) a HOMO level or a LUMO level of the organic semiconductor material. Further, as another reason, low affinity of different materials, i.e., the metal and the organic semiconductor material causes low physical adhesiveness, which in turn leads to the contact resistances.

In recent years, improvement in carrier injection of an electrode of an organic EL device has been an object. For example, Patent Literature 1 solves the object by providing a layer having an electric dipole moment. The electric dipole moment disclosed in Patent Literature 1 is directed to a hole injection electrode from an organic layer. Note that “direction of electric dipole moment” is defined as a direction of a vector of a polarized material or molecules to a positive pole from a negative pole. That is, in a case where the hole is injected to the organic semiconductor layer from the electrode, providing a layer having the electric dipole moment which has a direction opposite to a transferring direction of the hole can reduce the energy gaps.

Meanwhile, Patent Literature 2 discloses an arrangement of the organic transistor based on the aforementioned conception. Specifically, Patent Literature 2 discloses an arrangement in which an injection promoting layer having an electric dipole moment is provided between the organic semiconductor layer and the source electrode and/or between the organic semiconductor layer and the drain electrode.

Further, Patent Literature 3 discloses an organic field effect transistor as illustrated in FIG. 10. The organic field effect transistor of FIG. 10 includes a gate electrode 102, a gate insulating layer 103, a semiconductor layer 104, a source electrode 107, and a drain electrode 108. The source electrode 107 is constituted by a compound layer 105 made from an accepter compound and a conductive layer 106, and the drain electrode 108 is constituted by a compound layer 105′ made from an accepter compound and a conductive layer 106′. The compound layers 105 and 105′ are each placed on the semiconductor layer 104, and the semiconductor layer 104 contains a polymer having an ionization potential of 5.0 eV or more. The acceptor compound represents a compound indicating electron acceptance with respect to the polymer, and specific examples of the acceptor compound encompass tetracyanoquinodimethane, tetracyanotetrafluoroquinodimethan, and a fullerene derivative.

### CITATION LIST

Patent Literatures

Patent Literature 1

Japanese Patent Application Publication Tokukai No. 2002-270369 A (Sep. 20, 2002)

Patent Literature 2

Japanese Patent Application Publication Tokukai No. 2005-294785 A (Oct. 20, 2005)

Patent Literature 3

Japanese Patent Application Publication Tokukai No. 2008-270734 (Nov. 6, 2008)

### SUMMARY OF INVENTION

### Technical Problem

However, Patent Literature 2 does not have an arrangement to reduce the contact resistances enough, specifically, Patent Literature 2 cannot reduce enough the contact resistances of the whole organic transistor in which a carrier is transferred from the source electrode to the drain electrode.

A reason why the contact resistances are not reduced is considered as follows: the contact resistance generated when a carrier is injected to the organic semiconductor layer from the source electrode is reduced by providing the layer having the electric dipole moment, however, the contact resistance generated when a carrier is drawn out to the drain electrode from the organic semiconductor layer is not reduced.

Further, it is also considered that, in a case where the transistor is operated repeatedly, an OFF-current is increased and an ON/OFF ratio is accordingly reduced because a carrier is not thoroughly drawn out to the drain electrode.

Further, in a case of the arrangement of Patent Literature 3, the following is considered: when providing the compound layer made from the acceptor compound, the compound layer is apt to receive, between the source electrode and the organic semiconductor layer, an electron of the organic semiconductor layer, so that the contact resistance generated when a hole is injected to the organic semiconductor layer from the source electrode is reduced. However, when the compound layer receives, between the drain electrode and the organic semiconductor layer, an electron of the organic semiconductor layer, the hole is apt to be drawn out to the drain electrode from the organic semiconductor layer. This brings an opposite effect to the effect which can be obtained when the hole is drawn out to the drain electrode from the organic semiconductor layer, and therefore does not lead to improvement in contact resistance. Also in this case, it is considered that, in a case where a transistor is operated repeatedly, the OFF-current is increased and the ON/OFF ratio is accordingly reduced.

That is, the conventional organic transistors are not secured to demonstrate stable operation.

### Solution to Problem

The present invention has been made in view of the aforementioned problem, and an object of the present invention is to provide: an organic transistor that demonstrates stable operation and reduces (i) a contact resistance between an organic semiconductor layer and a source electrode and (ii) a contact resistance between the organic semiconductor layer and a drain electrode; and a method for fabricating the organic transistor.

That is, in order to attain the aforementioned object, an organic transistor according to the present invention includes: a gate electrode; a source electrode; a drain electrode; a gate insulating layer; an organic semiconductor layer provided between the source electrode and the drain electrode; an injection improvement layer provided between the source electrode and the organic semiconductor layer, the injection improvement layer being made from a material or molecules having an electric dipole moment in which a vector directed to a positive pole from a negative pole is directed to the source electrode from the organic semiconductor layer; and an extraction improvement layer provided between the drain electrode and the organic semiconductor layer, the extraction improvement layer being made from a material or molecules having an electric dipole moment in which such a vector is directed to the organic semiconductor layer from the drain electrode, the electric dipole moment of the material or the molecules of the extraction improvement layer having an absolute value being larger than that of the injection improvement layer.

The aforementioned arrangement includes the injection improvement layer provided between the source electrode and the organic semiconductor layer, and the extraction improvement layer provided between the drain electrode and the organic semiconductor layer. Further, the vector of the electric dipole moment of the injection improvement layer is directed to the source electrode from the organic semiconductor layer, meanwhile, the vector of the extraction improvement layer is directed to the organic semiconductor layer from the drain electrode. Therefore, the organic transistor containing a hole as a carrier can reduce (i) the contact resistance between the organic semiconductor layer and the source electrode and (ii) the contact resistance between the organic semiconductor layer and the drain electrode.

Further, the organic transistor does not only include the improvement layers, but also is arranged so that the absolute value of the electric dipole moment of the material or the molecules of the extraction improvement layer is lager than that of the injection improvement layer. Therefore, all holes, which have been injected from the source electrode during operation of the transistor, can be drawn out (extracted) from the organic semiconductor layer to the drain electrode. This makes it possible that reduction in contact resistance leads to reduction in OFF current to thereby prevent reduction in ON/OFF ratio in a case where the transistor is operated two times or more. This can contribute to attain stable transistor operation.

Further, in order to attain the aforementioned object, another organic transistor according to the present invention includes: a gate electrode; a source electrode; a drain electrode; a gate insulating layer; an organic semiconductor layer provided between the source electrode and the drain electrode; an injection improvement layer provided between the source electrode and the organic semiconductor layer, the injection improvement layer being made from a material or molecules having an electric dipole moment in which a vector directed to a positive pole from a negative pole is directed to the organic semiconductor layer from the source electrode; and an extraction improvement layer provided between the drain electrode and the organic semiconductor layer, the extraction improvement layer being made from a material or molecules having an electric dipole moment in which such a vector is directed to the drain electrode from the organic semiconductor layer, the electric dipole moment of the material or the molecules of the extraction improvement layer having an absolute value being larger than that of the injection improvement layer.

The aforementioned arrangement includes the injection improvement layer provided between the source electrode and the organic semiconductor layer, and the extraction improvement layer provided between the drain electrode and the organic semiconductor layer. Further, the vector of the electric dipole moment of the injection improvement layer is directed to the organic semiconductor layer from the source electrode, meanwhile, the vector of the extraction improvement layer is directed to the drain electrode from the organic semiconductor layer. Therefore, the organic transistor containing an electron as a carrier can reduce (i) the contact resistance between the organic semiconductor layer and the source electrode and (ii) the contact resistance between the organic semiconductor layer and the drain electrode.

Further, the organic transistor does not only include the improvement layers, but also is arranged so that the absolute value of the electric dipole moment of the material or the molecules of the extraction improvement layer is lager than that of the injection improvement layer. Therefore, all electrons, which have been injected from the source electrode during operation of the transistor, can be drawn out (extracted) from the organic semiconductor layer to the drain electrode. This makes it possible that reduction in contact resistance leads to reduction in OFF current to thereby prevent reduction in ON/OFF ratio in a case where the transistor is operated two times or more. This can contribute to attain stable transistor operation.

Further, in order to attain the aforementioned object, a method for fabricating the organic transistor according to the present invention is a method for fabricating an organic transistor having the aforementioned arrangement, the method includes the steps of: (a) forming the source electrode on the gate insulating layer; (b) forming the injection improvement layer on the source electrode; (c) forming the drain electrode on the gate insulating layer on the gate insulating film; (d) forming the extraction improvement layer on the drain electrode; and (e) forming the organic semiconductor layer so as to be brought into contact with the injection improvement layer and the extraction improvement layer after performing the steps (b) and (d).

Further, the organic transistor does not only include the improvement layers, but also is arranged so that the absolute value of the electric dipole moment of the material or the molecules of the extraction improvement layer is lager than that of the injection improvement layer. Therefore, all carriers, which have been injected from the source electrode during operation of the transistor, can be drawn out (extracted) from the organic semiconductor layer to the drain electrode. This makes it possible to reduce the contact resistance generated when the carriers are drawn out to the drain electrode from the organic semiconductor layer. Accordingly, it is possible to provide the organic transistor by which the contact resistances of the whole organic transistor (in which the carriers are transferred from the source electrode to the drain electrode) are reduced. In particular, this makes it possible that reduction in contact resistance leads to reduction in OFF current to thereby prevent reduction in ON/OFF ratio. This can contribute to attain stable transistor operation.

The injection improvement layer and the extraction improvement layer can be individually formed on the source electrode and on the drain electrode, respectively, by forming firstly the source electrode and the injection improvement layer and then forming the drain electrode and the extraction improvement layer or by forming firstly the drain electrode and the extraction improvement layer and then forming the source electrode and the injection improvement layer, even if the source electrode and the drain electrode are made from the same material and the material could be bound to an injection improvement layer material and an extraction improvement layer material.

Further, in another method for fabricating the organic transistor including the aforementioned arrangement according to the present invention, it is preferable that, in the step (b), the injection improvement layer is a self-assembled monomolecular layer or a self-assembled molecular multilayer in which self-assembled molecular layers are stacked. Further, it is preferable that, in the step (d), the extraction improvement layer is a self-assembled monomolecular layer or a self-assembled molecular multilayer in which self-assembled molecular layers are stacked.

When a method for forming a self-assembled monomolecular layer or a self-assembled multilayer is employed as a method for forming the injection improvement layer and the extraction improvement layer, a layer having an electric dipole moment can be formed in a state of an atmospheric pressure and a low temperature of 150° C. or less. This can reduce deformation of or damage to a thermoplastic substrate.

For a fuller understanding of the nature and advantages of the invention, reference should be made to the ensuing detailed description taken in conjunction with the accompanying drawings.

### ADVANTAGEOUS EFFECTS OF INVENTION

As described above, an organic transistor according to the present invention includes: an injection improvement layer provided between a source electrode and an organic semiconductor layer; and an extraction improvement layer provided between a drain electrode and the organic semiconductor layer, an absolute value of the electric dipole moment of the material or the molecules of the extraction improvement layer being larger than that of the injection improvement layer.

Further, a method for fabricating the organic transistor including the aforementioned arrangement according to the present invention, the method includes the steps of: (a) forming the source electrode on the gate insulating layer; (b) forming the injection improvement layer on the source electrode; (c) forming the drain electrode on the gate insulating layer on the gate insulating film; (d) forming the extraction improvement layer on the drain electrode; and (e) forming the organic semiconductor layer so as to be brought into contact with the injection improvement layer and the extraction improvement layer after performing the steps (b) and (d).

The aforementioned arrangement can provide: an organic transistor that demonstrates stable operation and reduces (i) a contact resistance between an organic semiconductor layer and a source electrode and (ii) a contact resistance between the organic semiconductor layer and an drain electrode; and a method for fabricating the organic transistor.

### BRIEF DESCRIPTION OF DRAWINGS

FIG. 1

FIG. 1 is a sectional view illustrating an arrangement of an organic transistor according to an embodiment of the present invention.

FIG. 2

FIG. 2 illustrates partial arrangement of an injection improvement layer material and an extraction improvement layer material of an organic transistor according to an embodiment of the present invention.

FIG. 3

FIG. 3 illustrates partial arrangement of an injection improvement layer material and an extraction improvement layer material of an organic transistor according to an embodiment of the present invention.

FIG. 4

FIG. 4 is a sectional view illustrating a fabricating step of an organic transistor according to an embodiment of the present invention.

FIG. 5

FIG. 5 is a sectional view illustrating a fabricating step of another organic transistor according to an embodiment of the present invention.

FIG. 6

FIG. 6 is a sectional view illustrating a fabricating step of another organic transistor according to an embodiment of the present invention.

FIG. 7

FIG. 7 is a sectional view illustrating a fabricating step of another organic transistor according to an embodiment of the present invention.

FIG. 8

FIG. 8 is a sectional view illustrating a modification of an organic transistor according to an embodiment of the present invention.

FIG. 9

FIG. 9 is a sectional view illustrating an arrangement of an organic transistor of a comparative example.

FIG. 10

FIG. 10 is a sectional view illustrating an arrangement of a conventional art.

### DESCRIPTION OF EMBODIMENTS

### Embodiment 1

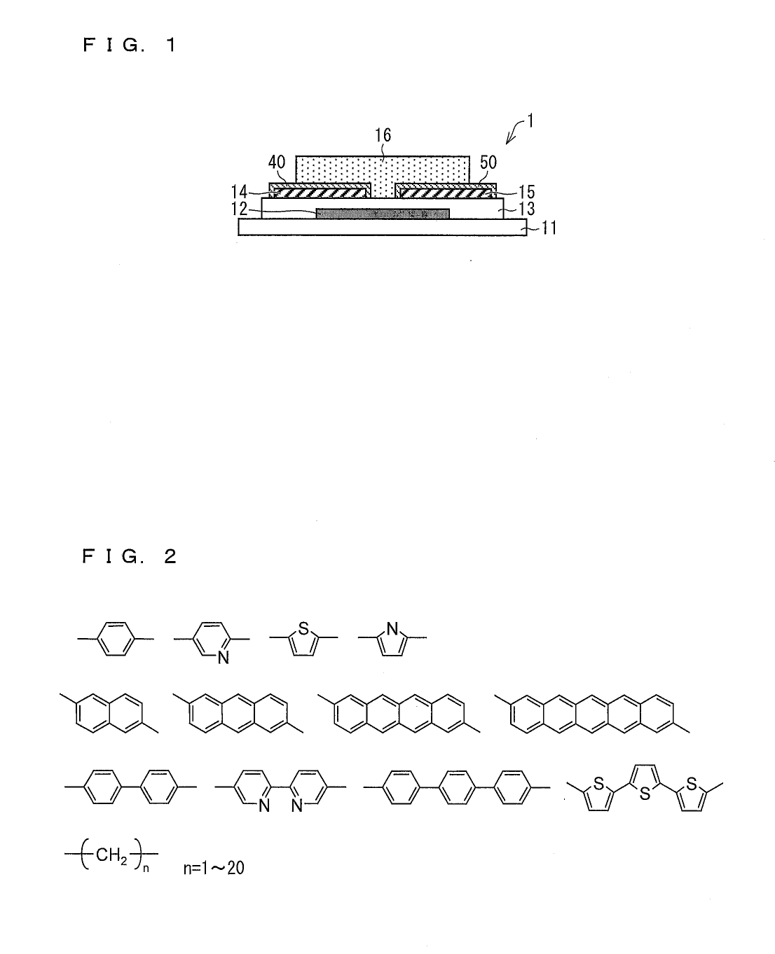

An embodiment according to the present invention will be described below with reference to FIGS. 1 to 5.

An organic transistor according to the present embodiment includes an injection improvement layer provided between a source electrode and an organic semiconductor layer, and an extraction improvement layer provided between a drain electrode and the organic semiconductor layer. In addition, an electric dipole moment of a material or molecules in the extraction improvement layer has an absolute value larger than that of the injection improvement layer.

Hereinafter, an arrangement of the organic transistor will be firstly described, and a method for fabricating the organic transistor will be described subsequently.

(1) Arrangement of Organic Transistor

FIG. 1 is a sectional view illustrating the arrangement of the organic transistor according to the present embodiment. An organic transistor 1 is a field effect transistor which can be provided on various semiconductor devices. As illustrated in FIG. 1, the organic transistor 1 includes a substrate 11, a gate electrode 12, a gate insulating layer 13, a source electrode 14, and a drain electrode 15, an organic semiconductor layer 16, an injection improvement layer 40, and an extract improvement layer 50.

(Substrate)

Examples of the substrate 11 encompass a silicon substrate, a quartz substrate, a glass substrate, and a resin substrate made from polycarbonate, polyether ether ketone, polyimide, polyester, polyether sulfone, etc. In particular, when considering to provide the organic transistor 1 to a flexible device, a resin substrate is preferably used.

A thickness of the substrate 11, which is applied to the present invention, can be within the range from, for example, 10 μm to 1 mm. However, the present invention is not limited thereto.

(Gate Electrode)

The gate electrode 12 is formed on the substrate 11 by means of photolithography or the like.

For example, the gate electrode 12 is made from: a metal such as gold (Au), silver (Ag), copper (Cu), platinum (Pt), palladium (Pd), iron (Fe), aluminum (Al), tantalum (Ta), or chromium (Cr); an oxide conductor such as indium tin oxide (ITO), zinc oxide (ZnO), or tin oxide (SnO₂); or a transparent conductive material made from indium oxide and zinc oxide each of which is one of the oxide conductors. Further, two or more kinds of these materials may be combined.

Alternatively, the gate electrode 12 may be made from an organic material such as polyaniline or polythiophene, or may be formed by applying a conductive ink. The electrodes, which are made from these organic materials or is formed by applying the conductive ink, can be formed with extreme ease. Specific examples of a method for applying ink encompass spin coating, a cast method, or a dip-coating method, or alternatively, a printing method such as an inkjet printing method, screen printing, or gravure printing. By using any one of these printing methods, pattern printing can be performed.

Although a thickness of the gate electrode 12 is changed in accordance with conductivity of a material of the gate electrode 12, the thickness can be within the range from 50 nm to 1000 nm. A lower limit in the thickness of the gate electrode 12 is dependent on the conductivity of an electrode material and an adhesive strength between the gate electrode 12 and the substrate 11. Meanwhile, an upper limit of the thickness of the gate electrode 12 should be such that, when the gate insulating layer 13 described below and a pair of the source electrode 14 and the drain electrode 15 are provided, (i) a step between the substrate 11 and the gate electrode 12 is enough insulated with the gate insulating layer 13 and (ii) the gate electrode 12 does not cause a break in the electrode patterns of the source electrode 14 and the drain electrode 15 which are formed on the gate insulating layer 13.

(Gate Insulating Layer)

As illustrated in FIG. 1, the gate insulating layer 13 is formed, on a surface on which the gate electrode 12 of the substrate 11 is formed, so as to cover the gate electrode 12 and the step of the gate electrode 12.

The gate insulating layer 13 can be formed in the same way as the gate electrode 12, i.e., by applying a polymer material such as polychloroprene, polyethylene-telephthalate, polyoxymethylene, polyvinyl chloride, polyvinylidene fluoride, cyanoethylpullulan, polymethylmethacrylate, polysulfone, polycarbonate, polyvinyl phenol, polystyrene, or polyimide. Examples of a method for applying ink encompass spin coating, a cast method, or a dip-coating method, or alternatively, a printing method such as an inkjet printing method, screen printing, gravure printing, or flexography. By using any one of these printing methods, pattern printing can be performed.

Note that the gate insulating layer 13 may be formed by a known patterning process such as a CVD method. In this case, an inorganic material such as SiO₂, SiNx, or Al₂O₃, is preferably used. Further, two or more kinds of those materials may be combined.

It is preferable that the gate insulating layer 13 has (i) enough insulating property to reduce a leakage current and (ii) a large capacitance per unit volume. A thickness of the gate insulating layer 13 is set on the basis of the aforementioned (i) and (ii). Specifically, in a case where the gate insulating layer 13 is made from a polymer material, the thickness preferably falls within the range from 20 nm to 1000 nm. Meanwhile, in a case where the gate insulating layer is made from an inorganic material, the thickness preferably falls within the range from 10 nm to 500 nm. Further, an insulating layer, which is a self-assembled monomolecular layer (SAM: self-assembled monolayer) having long-chain alkyl (e.g., octadecylsilane self-assembled monomolecular layer (ODS-SAM)), has a thickness which can be reduced to as thin as about a molecule length and capacitance per unit volume which is accordingly increased. Therefore the insulating layer of the SAM is preferable. Further, it is desirable that the gate insulating layer 13 has a dielectric withstand voltage of 2 MV/cm or more, regardless of the kind of materials for forming the insulating layer.

(Source Electrode and Drain Electrode)

As illustrated in FIG. 1, the source electrode 14 and the drain electrode 15 are formed on the gate insulating layer 13.

For example, the source electrode 14 and the drain electrode 15 are made from: a metal such as gold (Au), silver (Ag), copper (Cu), platinum (Pt), palladium (Pd), iron (Fe), aluminum (Al), tantalum (Ta), or chromium (Cr); an oxide conductor such as indium tin oxide (ITO), zinc oxide (ZnO), or tin oxide (SnO₂); or a transparent conductive material made from indium oxide and zinc oxide each of which is one of the oxide conductors. In particular, the source electrode 14 and the drain electrode 15 are preferably made from Au, Ag, ITO, ZnO, SnO₂, or the transparent conductive material made from indium oxide and zinc oxide, to which the injection improvement layer 40 and the extraction improvement layer 50 mentioned below are chemically adhered with ease.

Both the source electrode 14 and the drain electrode 15 may be made from the same material or different materials. Using the same material can reduce a material cost. Meanwhile, using the different materials can reduce the number of process. Specifically, in a case where the injection improvement layer and the extraction improvement layer are the self-assembled monomolecular layers which are made from materials different from each other, surfaces of respective electrodes (bonds) are accordingly different from each other. The injection improvement layer and the extraction improvement layer are selected so as to be capable of combining to the source electrode 14 and the drain electrode 15, respectively, so that both the improvement layers can be formed at the same time. In contrast, in a case where the two improvement layers are the same self-assembled monomolecular layer, the following four steps need to be performed: forming the source electrode, forming the injection improvement layer, forming the drain electrode, and then forming the extraction improvement layer. In a case of using different materials, a combination of gold and ITO, or a combination of silver and ITO is preferable.

(Organic Semiconductor Layer)

The organic semiconductor layer 16 is formed on a channel region (charge transport path region) provided between the source electrode 14 and the drain electrode 15.

The organic transistor 1 of the present embodiment is a field effect transistor as described above, and can be used even if a carrier is an electron (n-type channel) or a hole (p-type channel). Accordingly, the organic semiconductor layer 16 can be made from a p-type channel material or an n-type channel material.

Specifically, examples of a material of the organic semiconductor layer 16 for a p-type channel encompass pentacene, rubrene, oligothiophene, polythiophene, and their alkyl-substituted derivatives. Further, as the material of the organic semiconductor layer 16 for the n-type channel, C₆₀ fullerene, pentacene fluoride, or perylene imide compound is preferable. In particular, pentacene and C₆₀ fullerene are preferable, because each of them has high carrier mobility and attains high-speed operation.

(Injection Improvement Layer and Extraction Improvement Layer)

The injection improvement layer 40 is provided between the source electrode 14 and the organic semiconductor layer 16. In a case where a carrier is a hole, the injection improvement layer 40 is made from a material or molecules having the electric dipole moment in which a vector (which is directed to a positive pole from a negative pole of the electric dipole moment) is directed to the source electrode 14. In a case where a carrier is an electron, the injection improvement layer 40 is made from a material or molecules having the electric dipole moment in which the vector is directed to the organic semiconductor layer 16.

Further, the extraction improvement layer 50 is provided between the drain electrode 15 and the organic semiconductor layer 16. In a case where a carrier is a hole, the extraction improvement layer 50 is made from a material or molecules having the electric dipole moment in which the vector is directed to the organic semiconductor layer 16. In a case where a carrier is an electron, the extraction improvement layer 50 is made from a material or molecules having the electric dipole moment in which the vector is directed to the drain electrode 15.

As described above, the absolute value of the electric dipole moment of the material or the molecules contained in the injection improvement layer 40 of the present invention is larger than that contained in the extraction improvement layer 50 of the present invention.

Specifically, at least one of the injection improvement layer 40 and the extraction improvement layer 50 is an organic thin film having the electric dipole moment, which organic thin film is formed by assembling the organic compounds each represented by the following chemical formula (1):

X-A-Y (1).

The organic thin film having the electric dipole moment means a thin film having a thickness corresponding to a size of one molecule. Note that the organic thin film may have structures each represented by chemical formula (1), and the structures may be partially covalently bound to each other and formed into a dimer, a trimer, or an oligomer-shape structure. However, the thickness of the thin film should correspond to one molecule.

A substituent X in the chemical formula (1) and atoms constituting the source electrode 14 and the drain electrode 15 are chemically bound to each other. This combines the electrodes and the molecules represented by the chemical formula (1), that is, the molecules represented by the chemical formula (1) assemble. In this way, the substituent X functions to form a self-assembled monomolecular layer.

Note that the injection improvement layer 40 and the extraction improvement layer 50 of the present embodiment are the SAMs. However, the present invention is not limited thereto, and any one of the injection improvement layer 40 and the extraction improvement layer 50 may be the SAM. Forming an improvement layer from the SAM can reduce the thickness of the at least one improvement layer as thin as about a molecule length, so that a resistance of the improvement layer itself can be reduced. Further, the SAM has a structure in which single molecules are arrayed. Therefore, forming the improvement layer from the SAM leads to an easy control on an direction of the electric dipole moment.

Note that any one of the injection improvement layer and the extraction improvement layer may be a self-assembled molecular multilayer (a film having a structure in which the plurality of monomolecular layers are stacked by chemical bonding and including a repeating unit of a main chain skeleton). Molecules constituting the self-assembled molecular multilayer thus formed can be represented by the chemical formula (1) as well as the molecules constituting the monomolecular layer. “A”, which is a molecular skeleton, has an arrangement in which an aromatic skeleton or an aliphatic skeleton described below is chemically bound to “X” and “Y”. Specific examples of such chemical bond encompass an imine bond, an amide bond, an imide bond, a siloxane bond, an urethane bond, an urea bond, and a triazole ring. Unlike a case of using only the monomolecular layer, using the self-assembled molecular multilayer can easily control the film thickness, the direction of the electric dipole moment, and the magnitude thereof.

Specific examples of the substituent X encompass: —SH, —SiR¹₃, —POR²₂, —COOH, —CN, or —SiH₃ (Note that any one of R¹ is —OMe, —OEt, or —Cl, and any one of R² is —OH or —Cl).

It is particularly preferable that the substituent X is a thiol group (—SH). When the substituent X is the thiol group, atoms constituting the source electrode 14 and the drain electrode 15 and the thiol group can be covalently bound to each other, so that a distance between the thiol group and the electrode atoms can be relatively shortened. This makes it possible to further reduce the aforementioned contact resistances. In particular, if (i) at least one of the source electrode 14 and the drain electrode 15 is selected from a material including gold (Au) atom and (ii) the gold (Au) atom and the thiol group (—SH) are chemically bound to each other, the at least one improvement layer can be immobilized on the electrodes. This makes it possible to prevent deterioration of the at least one improvement layer, which is affected by an electric field generated during driving of the organic transistor 1, and in addition to prolong a life of the organic transistor 1.

Aromatic thiol, which is formed by combining a main chain skeleton A described below and the thiol group of the substituent X, has a HOMO existing also around a sulfur atom. The orbital is electrically conductive, and extends near the electrode material. This reduces a resistance, which is generated in a part connected between the improvement layer and the corresponding electrode. It is therefore possible to further reduce the contact resistance of the transistor.

A substituent Y in the chemical formula (1) is brought into contact, on a surface of the improvement layer, with the organic semiconductor layer 16. The substituent Y is an electron donating substituent or an electron withdrawing substituent. The electron donating substituent and the electron withdrawing substituent have a negative Hammett's substituent constant and a positive Hammett's substituent constant, respectively.

Specific examples of the electron withdrawing substituent Y¹, which can be used as substituent Y, encompass —F, —Br, —Cl, —I, —NO₂, —CN, —Si(OR¹)₃, —CF₃, —CH₂Cl, —CHO, or —COOR¹ (where R¹ is a linear C1 to C3 alkyl group).

Specific examples of the electron donating substituent Y², which can be used as a substituent Y, encompass —OH, —OR¹, —NH₂, —NHR¹, —NR¹, —SH, —SR¹, or —R¹.

In a case where the substituent Y is the electron withdrawing substituent, the periphery of the electron withdrawing substituent Y¹ takes a negative charge. Therefore the injection improvement layer and the extraction improvement layer can each have the electric dipole moment which is directed to the electrodes from the organic semiconductor layer. Further, in a case where the substituent Y is the electron donating substituent, the periphery of the electron donating substituent Y² takes a positive charge. Therefore the injection improvement layer and the extraction improvement layer can each have the electric dipole moment which is directed to the organic semiconductor layer from the electrodes.

The main chain skeleton A in the chemical formula (1) needs to have any one of structures illustrated in FIG. 2. It is preferable that the main chain skeleton A is an aromatic skeleton which is a skeleton including a π-electron (for example, a skeleton having a monocycle structure such as benzene, pyridine, thiophene, or pyrrole; a skeleton having an annelation structure such as naphthalene, anthracene, tetracene, or pentacene; or a skeleton having a polycyclic structure such as biphenyl, bipyridyl, terphenyl, or terthiophene). In addition, it is also preferable that the main chain skeleton A is an aliphatic skeleton which is a skeleton including a σ-electron, for example, linear alkane having the carbon number from 1 to 20. The linear alkane has a molecular cross-sectional area smaller than the aromatic skeleton. This makes it possible to form a self-assembled monomolecular layer having a high molecular density. As a result, the number of molecules having the electric dipole moment is increased per unit area, and accordingly an effect of injecting and extracting a carrier is improved. Further, the carbon number of the linear alkane is preferably 20 or less. A reason for this is as follows: the resistance of the self-assembled monomolecular layer itself is increased as the carbon number of the linear alkane is increased, so that (i) the contact resistance between the organic semiconductor layer and the source electrode and (ii) the contact resistance between the organic semiconductor layer and the drain electrode may be disadvantageously increased.

The absolute value of the electric dipole moment is a value in a longitudinal direction of the molecules (a direction perpendicular to a surface of the electrode) which is calculated by means of a density functional method (B3LYP/6-31+G (d, p)). Materials for forming the injection improvement layer 40 or the extraction improvement layer 50 can be appropriately selected on the basis of the value thus calculated.

Specifically, it is preferable that a difference of the absolute values of the electric dipole moments between the injection improvement layer 40 and the extraction improvement layer 50 falls within the range from 0.01 D to 20 D.

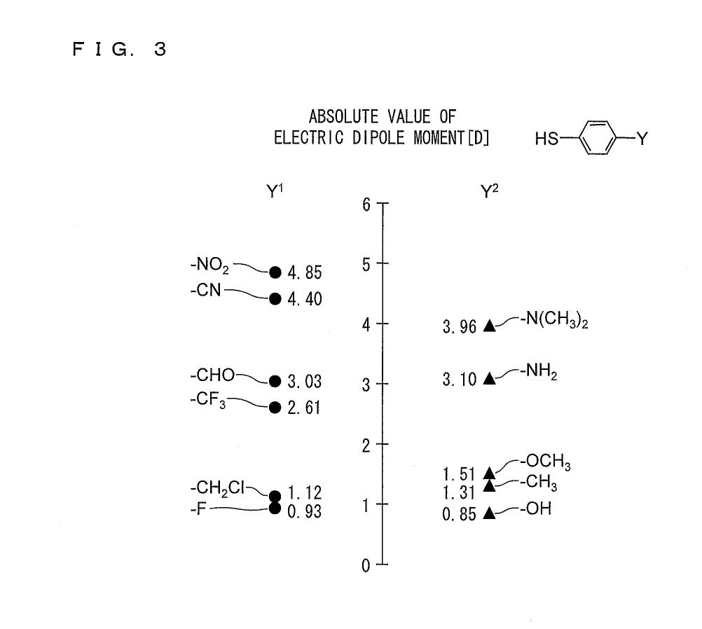

FIG. 3 illustrates an example of the absolute value of the electric dipole moment in the organic compound in which “A” in the chemical formula (1) is an aromatic ring and the substituent X is SH (thiol) group. A combination of the extraction improvement layer and the injection improvement layer is arbitrarily selected on the basis of FIG. 3 so that the absolute value of the extraction improvement layer is larger than that of the injection improvement layer.

Among the combinations illustrated in FIG. 3, preferable in a case where a carrier is a hole in particular are combinations in which the organic compound Y constituting the injection improvement layer 40 is a formyl group or a trifluoromethyl group and the organic compound Y constituting the extraction improvement layer 50 is an amino group or a dimethylamino group. In a case where a carrier is an electron, preferable are combinations in which the organic compound Y constituting the injection improvement layer 40 is an amino group or a dimethylamino group, and the organic compound Y constituting the extraction improvement layer 50 is a nitro group or a cyano group. This is because the absolute value of the electric dipole moment of the combination selected from the nitro group and the cyano group is larger than any other combinations selected from other functional groups, and can therefore reduce the contact resistance greatly.

Note that the present invention is not limited to the exemplified benzenethiol derivatives, and other functional groups (except for the substituent X) and other skeletons (except for the main chain skeleton A) can be used if an absolute value of an electric dipole moment is calculated and then an extraction improvement layer has larger absolute value than the injection improvement layer.

Further, in stead of the aforementioned self-assembled monomolecular layer, the inorganic material such as lithium fluoride or molybdenum oxide may be used. Further, any material can be used as long as the material has the electric dipole moment and the direction of the electric dipole moment can be directed in one direction.

(2) Fabricating of Organic Transistor

Next, a method for fabricating the organic transistor of the present embodiment including the aforementioned arrangement will be described.

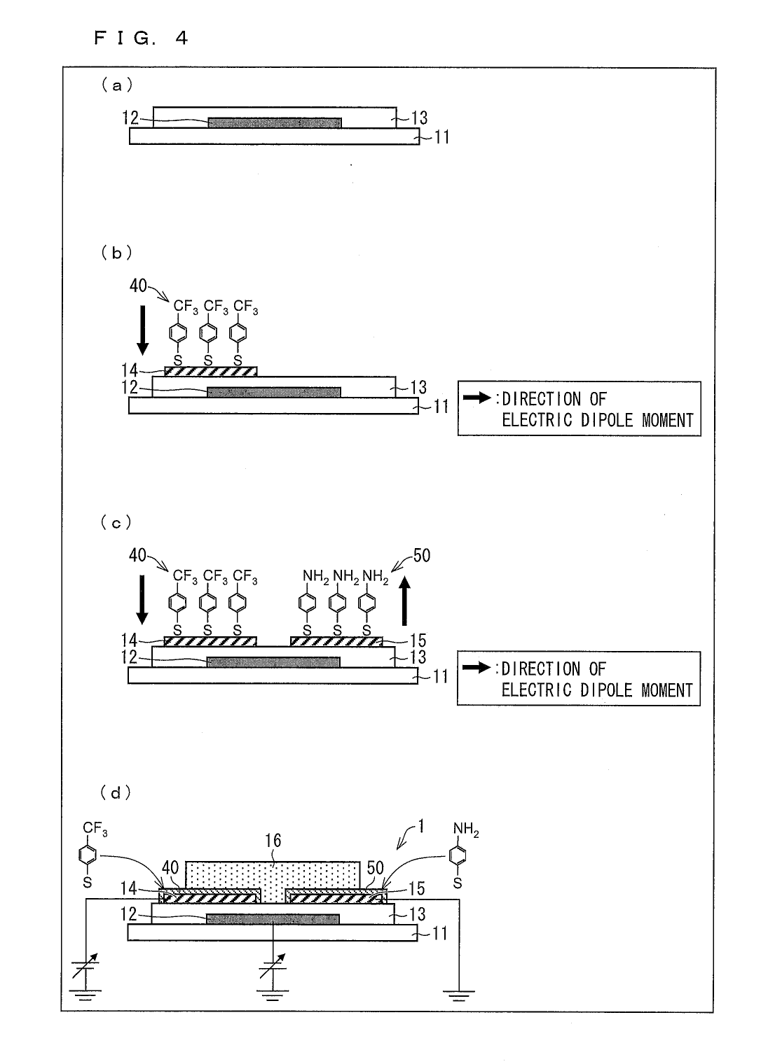

FIG. 4 illustrates a method for fabricating the organic transistor of the present embodiment.

(Step for Forming Gate Electrode)

First, a gate electrode material is formed on a whole surface of the substrate 11 by, for example, sputtering, and is then subjected to patterning by means of the known photolithography. In this way, the gate electrode 12 is formed as illustrated in (a) of FIG. 4. In Example 1 described below, an aluminum film having a thickness of 60 nm serves as the gate electrode 12.

(Step for Forming Gate Insulating Layer)

Next, a gate insulating layer material is sputtered to cover the gate electrode 12. In this way, the gate insulating layer 13 is formed as illustrated in (a) of FIG. 4. In Example 1 described below, silicon dioxide having a film thickness of 200 nm serves as the gate insulating layer 13.

(Step for Forming Source Electrode)

Next, a source electrode material is vacuum deposited via a metal mask. In this way, the source electrode 14 is formed as illustrated in (b) of FIG. 4. In Example 1 described below, chromium of 5 nm and gold of 60 nm are vacuum deposited in this order via a metal mask to thereby form the source electrode 14. The chromium herein functions to adhere the gold and the substrate 11 to each other.

(Step for Forming Injection Improvement Layer)

Next, the aforementioned material serving as an injection improvement layer material is formed into a self-assembled monomolecular layer (SAM) on the source electrode 14 thus formed. In this way, the injection improvement layer 40 is formed as illustrated in (b) of FIG. 4. In Example 1 described below, p-trifluoromethyl benzene thiol is used as an injection improvement layer material.

Note that a step for forming an injection improvement layer is not limited to the aforementioned method. Alternatively, the SAM may be formed as follows: sealing a substrate and a material for forming the SAM within an airtight container; heating the substrate and the material at about 50° C. to 150° C.; and washing away the substrate with use of a solution in order to remove a material which is physically attached to the substrate. Further, another method for forming the injection improvement layer is as follows: applying a solution of a material for forming the SAM onto a substrate by means of spin coating or dip coating; heating the substrate at about 50° C. to 150° C. in order to bond the substrate and the solution chemically; and washing away the substrate with use of a solution in order to remove a material excessively adhered to the substrate.

Note that, as described above, both the injection improvement layer 40 and the extraction improvement layer 50 are not limited to the SAM or a self-assembled molecular layer, as long as the absolute value of the electric dipole moment in the extraction improvement layer 50 is larger than that of the injection improvement layer 40. Alternatively, for example, the injection improvement layer can be made from the inorganic material such as lithium fluoride or molybdenum oxide by means of vacuum depositing or sputtering.

(Step for Forming Drain Electrode)

Next, the material for forming the drain electrode is vacuum deposited on the gate insulating layer 13 thus formed via a metal mask. In this way, the drain electrode 15 is formed as illustrated in (c) of FIG. 4. A distance (channel length) between a side of the source electrode 14 and a side of the drain electrode 15, which sides are adjacent to each other, can be within the range from 5 μm to 200 μm. Further, a side of the source electrode 14 and a side of the drain electrode 15, which sides are adjacent to each other, each have a length within the range from 100 μm to 10000 μm. As illustrated in (c) of FIG. 4, the drain electrode 15 is formed by vacuum depositing chromium of 5 nm and gold of 60 nm in this order via the metal mask.

(Step for Forming Extraction Improvement Layer)

Further, the extraction improvement layer material is formed as the SAM on the drain electrode 15. In this way, the extraction improvement layer 50 is formed on the drain electrode 15. In Example 1 described below, the SAM is made from p-aminobenzenethiol.

Note that the extraction improvement layer is formed in the same way as the injection improvement layer as follows: sealing a substrate and a material for forming the SAM within an airtight container; heating the substrate and the material at about 50° C. to 150° C.; and washing away the substrate with use of a solution in order to remove a material which is physically attached to the substrate. Further, another method for forming the injection improvement layer is as follows: applying a solution of a material for forming the SAM onto a substrate by means of spin coating or dip coating; heating the substrate at about 50° C. to 150° C. in order to bond the substrate and the solution chemically; and washing away the substrate with use of a solution in order to remove a material excessively adhered to the substrate.

(Step for Forming Organic Semiconductor Layer)

Next, as illustrated in (d) of FIG. 4, the organic semiconductor layer 16 is formed by vacuum depositing the material for forming the organic semiconductor layer) so that the organic semiconductor layer 16 can be brought into contact with the injection improvement layer and the extraction improvement layer. The organic semiconductor layer 16 can have a thickness within the range from 10 nm to 1000 nm. Pentacene used as the material of the organic semiconductor layer in Example 1 is formed, via the metal mask, into the organic semiconductor layer 16 having the thickness of 60 nm.

The organic transistor of the present embodiment can be fabricated by the aforementioned methods.

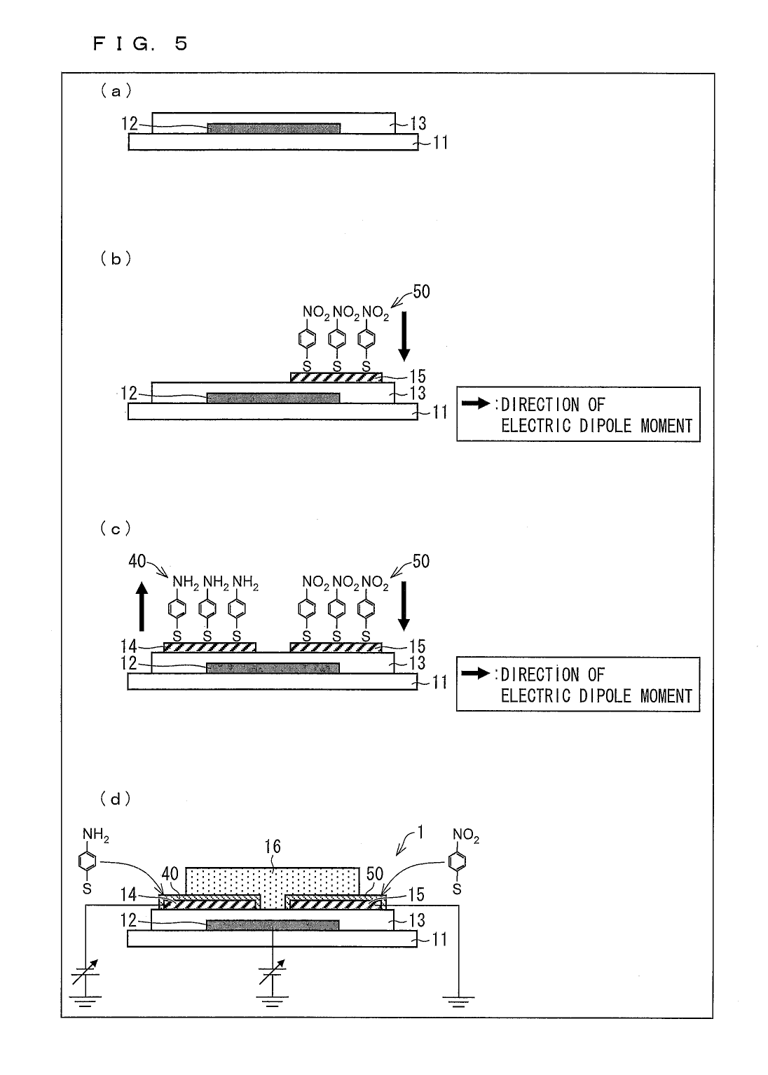

Note that, as the method for fabricating the organic transistor, (Step for forming gate insulating layer), (Step for forming source electrode), (Step for forming injection improvement layer), (Step for forming drain electrode), (Step for forming extraction improvement layer), and (Step for forming organic semiconductor layer) are performed in this order. However, a method for fabricating an organic transistor is not limited thereto, and a method illustrated in FIG. 5 may be performed instead.

In another example of the method for fabricating the organic transistor which is illustrated in FIG. 5, (Step for forming gate insulating layer) illustrated in (a) of FIG. 5, (Step for forming drain electrode) and (Step for forming extraction improvement layer) illustrated in (b) of FIG. 5, (Step for forming source electrode) and (Step for forming injection improvement layer) illustrated in (c) of FIG. 5, and (Step for forming organic semiconductor layer) illustrated in (d) of FIG. 5 are performed in this order. This example of the method will be described in Example 2.

(Organic Transistor Properties)

The organic transistor, which is formed in the aforementioned method and includes an organic semiconductor layer made from pentacene, has properties having relatively satisfactory values: mobility of about 1.0 cm²/V·s and an ON/OFF ratio of about 10⁶.

Further, (i) the contact resistance between the organic semiconductor layer and the source electrode and (ii) the contact resistance between the organic semiconductor layer and the drain electrodes are reduced to about one-tenth in comparison with a device of below-mentioned Comparison Example 1 which does not have an injection improvement layer and an extraction improvement layer. That is, forming the injection improvement layer and the extraction improvement layer on the source electrode and the drain electrode, respectively, leads to reduction in contact resistance.

Furthermore, even if the organic transistor of the present embodiment is evaluated in terms of its transistor properties after the organic transistor is operated repeatedly, a reduction in the ON/OFF ratio is observed and the organic transistor demonstrates stable operation. Note that, when evaluating an arrangement (which does not have the injection improvement layer and the extraction improvement layer) of the below-mentioned Comparison Example 1 after an organic transistor of Comparison Example 1 was repeatedly operated, it was observed that the ON/OFF ratio was reduced by about one digit.

Details of the properties will be described below in Examples 1 and 2 and Comparison Example 1.

Note that a TLM method, which is a well-known method described in Solid-State Electronics 47(2003)259 etc., can be used for evaluating the contact resistances. Specifically, in a case of evaluating a drain current value Id in ON-state (Vg=−30V) when a voltage Vd from the source electrode to the drain electrode is −30 V, a whole resistance Rt from the source electrode to the drain electrode;

Rt=2Rc+Rch

is calculated from Rt=Vd/Id (where Rc represents the sum of (i) a contact resistance between the organic semiconductor layer and the source electrode and (ii) a contact resistance between the organic semiconductor layer and the drain electrode, and Rch represents a resistance of a channel section). Further, the Rt is plotted with respect to the channel length, and a value obtained when the channel length (y intercept) is 0 is determined as a contact resistance.

### Effect of Present Embodiment

The contact resistances can be reduced as described above because the organic transistor of the present embodiment, which has the aforementioned arrangement, includes the injection improvement layer provided between the source electrode and the organic semiconductor layer, and the extraction improvement layer provided between the drain electrode and the organic semiconductor layer. Furthermore, the organic transistor does not only include the improvement layers, but also is arranged so that an absolute value of the electric dipole moment of the organic compound of the material or the molecules of the extraction improvement layer is lager than that of the injection improvement layer. Therefore, all carriers in the organic semiconductor, which have been injected from the source electrode when the transistor is operated, can be drawn out (can be extracted) into the drain electrode. This makes it possible to reduce the contact resistance when the carriers are drawn out from the organic semiconductor layer to the drain electrode, and therefore to reduce the contact resistances of the whole organic transistor in which the carries are transferred from the source electrode to the drain electrode. This makes it possible that reduction in contact resistance leads to reduction in OFF current to thereby prevent reduction in ON/OFF ratio in a case where the transistor is operated two times or more. This can contribute to attain stable transistor operation.

Further, if, unlike the present invention, it is so arranged to generate (i) an energy gap between the organic semiconductor layer and the source electrode material and (ii) an energy gap between the organic semiconductor layer and the drain electrode material, it is necessary to bring the source electrode or the drain electrode into contact directly with the organic semiconductor layer. Generally, a metal (serving as an electrode material) and an organic semiconductor layer (serving as an organic material) have low affinity, so that physical adherence of the metal and the organic semiconductor layer becomes weak. This leads to increase in contact resistance. Meanwhile, in the present invention, each improvement layer can be made from a material having high affinity with the organic semiconductor layer (for example, in a case of using the SAMs, the SAMs are made from an organic material, so that they are satisfactorily attached to each other), so that the present invention has an advantage of highly reducing the contact resistances. Further, it is necessary to use two kinds of metals as materials in order to generate (i) the energy gap between the organic semiconductor layer and the source electrode material and (ii) the energy gap between the organic semiconductor layer and the drain electrode material. This leads to increase in material cost. The present invention also needs two kinds of improvement layer materials, however, the improvement layer materials are generally cheaper than the metal materials.

### Modification of Present Embodiment

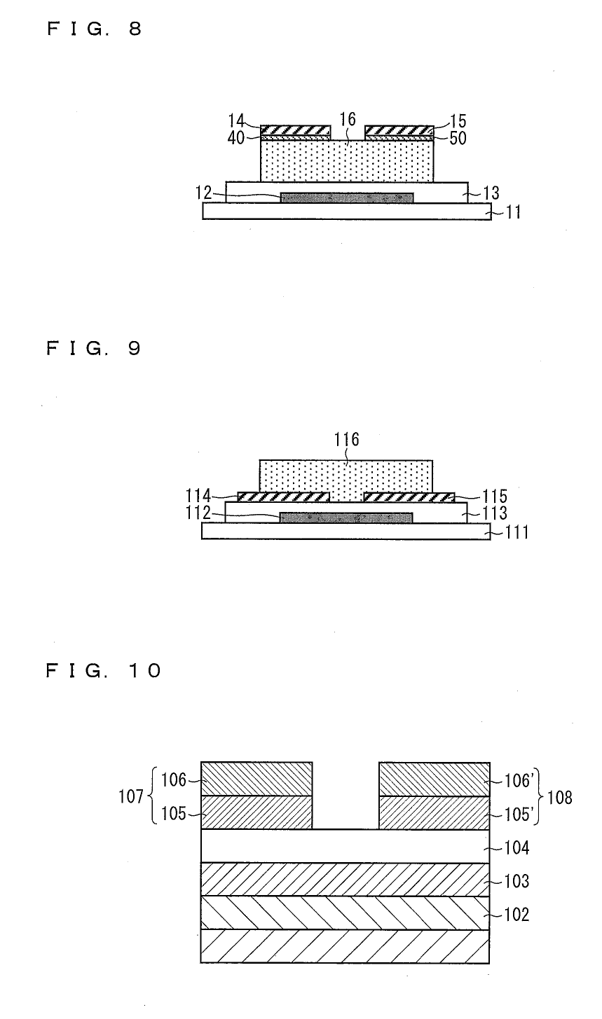

Note that the organic transistor having a bottom contact structure in which the substrate 11, the gate electrode 12, the gate insulating layer 13, the source electrode 14, the drain electrode 15, the injection improvement layer 40, the extraction improvement layer 50, and the organic semiconductor layer 16 are stacked in this order has been described in the present embodiment, however, the present invention is limited thereto. Alternatively, a structure illustrated in FIG. 8 may be used. The device structure of an organic transistor of FIG. 8 is a top contact structure in which a substrate 11, a gate electrode 12, a gate insulating layer 13, an organic semiconductor layer 16, an injection improvement layer 40, an extraction improvement layer 50, a source electrode 14, and the drain electrode 15 are stacked in this order. The bottom contact structure described in the present embodiment is preferable because the self-assembled monomolecular layers, which serve as the injection improvement layer and the extraction improvement layer, are easily formed on the source electrode and the drain electrode, respectively.

### EXAMPLE

Hereinafter, an organic transistor of the present invention will be described in detail with reference to Examples.

### Example 1

### Example of Arrangement of Embodiment 1

First, in a step for forming a gate electrode as illustrated in (a) of FIG. 4, a glass plate having a size of 25 mm×25 mm was formed as a substrate 11, and a gate electrode 12 was formed by forming an aluminum film having a thickness of 60 nm, i.e., by sputtering aluminum onto a whole surface of the substrate 11, and then by patterning the aluminum film by a known photolithography.

Next, in a step for forming a gate insulating layer, a gate insulating layer 13 was formed by sputtering silicon dioxide to have a thickness of 200 nm.

Next, in a step for forming a source electrode as illustrated in (b) of FIG. 4, a source electrode 14 was formed such that chromium of 5 nm and gold of 60 nm are vacuum deposited in this order via a metal mask. The chromium herein functions to cause the gold and the substrate 11 to adhere to each other.

Then, in a step for forming an injection improvement layer, a

SAM made from p-trifluoromethyl benzene thiol was formed on the source electrode 14 thus formed. As a specific forming method, the injection improvement layer was formed in such a manner that: 1 mM dehydrated ethanol solution of p-trifluoromethyl benzene thiolthiol was prepared; a substrate in which a gate electrode, a gate insulating layer, and also a source electrode were provided was dipped for three hours in the 1 mM dehydrated ethanol solution; and then p-trifluoromethyl benzene thiol adhered to the substrate excessively was removed by washing away the substrate with use of dehydrated ethanol. In this way, the injection improvement layer 40 was formed on the source electrode 14.

Next, in a step for forming a drain electrode as illustrated in (c) of FIG. 4, a drain electrode 15 was formed such that chromium of 5 nm and gold of 60 nm were vacuum deposited in this order via a metal mask. In Example 1, a channel length was 30, 40, 50, 75, or 100 μm, and a channel width was 1000 μm.

Further, in a step for forming an extraction improvement layer, a SAM made from p-aminobenzenethiol was formed on the drain electrode 15. As a specific forming method, the extraction improvement layer was formed in such a manner that: 1 mM dehydrated ethanol solution of p-aminobenzenethiol was prepared; a substrate in which the gate electrode 12, the gate insulating layer 13, the source electrode 14, and also the drain electrode 15 were provided was dipped for three hours in the 1 mM dehydrated ethanol solution; and then p-aminobenzenethiol adhered to the substrate excessively was removed by washing away the substrate with use of dehydrated ethanol. In this way, the extraction improvement layer 50 was formed on the drain electrode 15.

Next, in a step for forming an organic semiconductor layer as illustrated in (d) of FIG. 4, pentacene serving as an organic semiconductor layer 16 was vacuum deposited to the substrate so that the organic semiconductor layer 16 can be brought into contact with the injection improvement layer 40 and the extraction improvement layer 50. The organic semiconductor layer 16 made from pentacene have the thickness of 60 nm.

When the organic transistor obtained by means of the method for fabricating the organic transistor was evaluated, the organic transistor has properties of satisfactory values: mobility of about 0.8 cm²/V·s and an ON/OFF ratio of about 10⁶.

Further, (i) a contact resistance between an organic semiconductor and the source electrode and (ii) a contact resistance between an organic semiconductor and the drain electrode were evaluated by means of the aforementioned method. Then, the contact resistances were reduced to about one-tenth in comparison with the device of the following Comparison Example 1 which does not have the injection improvement layer and the extraction improvement layer. That is, forming the injection improvement layer and the extraction improvement layer on the source electrode and the drain electrode, respectively, leads to reduction in contact resistance.

Furthermore, the properties of the transistor were evaluated repeatedly, however, reduction in the ON/OFF ratio was not observed. That is, stable transistor operation was observed.

### Comparison Example 1

FIG. 9 illustrates a structure of an organic transistor formed in Comparison Example 1.

In Comparison Example 1, a gate electrode 112 and a gate insulating layer 113, which were made from a same material as Example 1, were formed on a glass substrate 111 by means of a same method as Example 1.

Next, a source electrode 114 and a drain electrode 115 were made from gold via a metal mask so as to have a thickness of 60 nm.

Then, an organic semiconductor layer 116 is formed by vacuum depositing pentacene so as to have a thickness of 60 nm. In this way, the organic transistor was formed.

When properties of the organic transistor thus formed in Comparison Example 1 were evaluated, the mobility was 0.1 cm²/V·s and the ON/OFF ratio was 10⁵, i.e., the mobility and the ON/OFF ratio in Comparison Example 1 were inferior to those in Example 1. Further, a contact resistance between the source electrode and an organic semiconductor and a contact resistance between the organic semiconductor layer and the drain electrode indicated ten times as large as those of Example 1.

### Example 2

### Another Example of Arrangement of Embodiment 1

In the present example, an organic transistor was formed on the basis of the method for fabricating the organic transistor illustrated in FIG. 5 and was then evaluated.

First, as illustrated in (a) of FIG. 5, a gate electrode 12 and a gate insulating layer 13, which were made from same materials as Example 1, were formed on a glass substrate 11 under a same condition as Example 1.

Next, as illustrated in (b) of FIG. 5, a drain electrode 15 was formed by vacuum depositing gold via a metal mask so as to have a thickness of 60 nm.

Then, a SAM, which was made from p-nitrobenzenethiol, was formed as an extraction improvement layer 50 on the drain electrode 15. As a specific forming method, the extraction improvement layer 50 was formed in such a manner that: 1 mM dehydrated ethanol solution of p-nitrobenzenethiol was prepared; a substrate in which the gate electrode, the gate insulating layer, and also the drain electrode were provided was dipped for three hours in the 1 mM dehydrated ethanol solution; and then p-nitrobenzenethiol adhered to the substrate excessively was removed with use of dehydrated ethanol.

Next, as illustrated in (c) of FIG. 5, a source electrode 14 was formed by vacuum depositing gold via a metal mask so as to have a thickness of 60 nm.

Then, a SAM, which was made from p-aminobenzenethiol, was formed as an injection improvement layer 40 on the drain electrode 14. As a specific forming method, the injection improvement layer 40 was formed in such a manner that: 1 mM dehydrated ethanol solution of p-aminobenzenethiol was prepared; a substrate in which the gate electrode, the gate insulating layer, the drain electrode, the extraction improvement layer, and also the source electrode were provided was dipped for three hours in the 1 mM dehydrated ethanol solution of p-aminobenzenethiol; and then p-aminobenzenethiol adhered to the substrate excessively was removed with use of dehydrated ethanol.

Next, as illustrated in (d) of FIG. 5, an organic semiconductor layer 16 was formed by vacuum depositing C₆₀ fullerene via a metal mask so as to have a thickness of 60 nm and to be brought into contact with the injection improvement layer and the extraction improvement layer.

When the organic transistor obtained by means of the method for fabricating the organic transistor was evaluated, the organic transistor has properties of satisfactory values: mobility of about 0.7 cm²/V·s and an ON/OFF ratio of about 10⁶.

Further, a contact resistance between an organic semiconductor and a contact resistance the organic semiconductor layer and the drain electrode were evaluated. Then, the contact resistances were reduced to one-fifth in comparison with those of the following Comparison Example 2 which did not have an injection improvement layer and an extraction improvement layer. That is, forming the injection improvement layer and the extraction improvement layer on the source electrode and the drain electrode, respectively, led to reduction in contact resistance even if a transistor was an n-type semiconductor transistor.

### Comparison Example 2

In Comparison Example 2, a gate electrode 12 and a gate insulating layer 13, which were made from a same material as Example 2, were formed on a glass substrate 11 by means of a same method as Example 2.

Next, a source electrode 14 and a drain electrode 15 were made from gold via a metal mask so as to have a thickness of 60 nm.

Next, an organic semiconductor layer 16 is formed by vacuum depositing C₆₀ fullerene so as to have a thickness of 60 nm. In this way, the organic transistor was formed.

A structure of the organic transistor thus formed is the same as the structure illustrated in FIG. 9.

When properties of the organic transistor thus formed in Comparison Example 2 were evaluated, the mobility was 0.3 cm²/V·s and the ON/OFF ratio was 10⁵. That is, the mobility in Comparison Example 2 was inferior to that in Example 2. Further, a contact resistance between the source electrode and an organic semiconductor and a contact resistance between the organic semiconductor layer and the drain electrode indicated five times as large as those of Example 2.

### Example 3

### Another Example of Arrangement of Embodiment 1

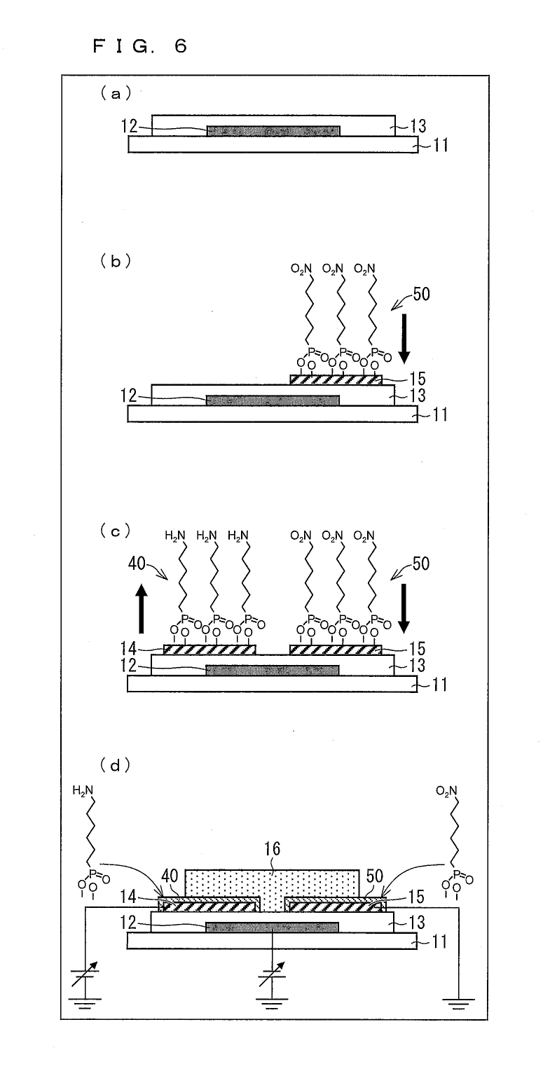

In the present example, an organic transistor was formed on the basis of a method for fabricating an organic transistor illustrated in FIG. 6 and was then evaluated.

First, as illustrated in (a) of FIG. 6, a gate electrode 12 and a gate insulating layer 13, which were made from a same material as Example 2, were formed on a glass substrate 11 under a same condition as Example 2.

Next, as illustrated in (b) of FIG. 6, a drain electrode 15 was formed by sputtering ITO via a metal mask so as to have a thickness of 60 nm.

Then, a SAM, which was made from 6-nitrohexane-1-phosphonic acid, was formed as an extraction improvement layer 50 on the drain electrode 15. As a specific forming method, the extraction improvement layer 50 was formed in such a manner that: 1 mM dehydrated ethanol solution of 6-nitrohexane-1-phosphonic acid was prepared; a substrate in which the gate electrode, the gate insulating layer, and also the drain electrode were provided was dipped for three hours in the 1 mM dehydrated ethanol solution; and then 6-nitrohexane-1-phosphonic acid adhered to the substrate excessively was removed with use of dehydrated ethanol.

Next, as illustrated in (c) of FIG. 6, a source electrode 14 was made from ITO by sputtering via a metal mask so as to have a thickness of 60 nm.

Then, a SAM, which was made from 6-aminohexan-1-phosphonic acid, was formed as an injection improvement layer 40 on the drain electrode 14. As a specific forming method, the injection improvement layer 40 was formed in such a manner that: 1 mM dehydrated ethanol solution of 6-aminohexan-1-phosphonic acid was prepared; a substrate in which the gate electrode, the gate insulating layer, the drain electrode, the extraction improvement layer, and also the source electrode were provided was dipped for three hours in the 1 mM dehydrated ethanol solution of 6-aminohexan-1-phosphonic acid; and then 6-aminohexan-1-phosphonic acid adhered to the substrate excessively was removed with use of dehydrated ethanol.

Next, as illustrated in (d) of FIG. 6, an organic semiconductor layer 16 was formed by vacuum depositing C₆₀ fullerene via a metal mask so as to have a thickness of 60 nm and to be brought into contact with the injection improvement layer and the extraction improvement layer.

When the organic transistor obtained by means of the method for fabricating the organic transistor was evaluated, the organic transistor has properties of satisfactory values: mobility of about 0.5 cm²/V·s and an ON/OFF ratio of about 10⁶.

Further, a contact resistance between an organic semiconductor and the source electrode and a contact resistance between the organic semiconductor and drain electrodes were evaluated. Then, the contact resistances were reduced to one-fourth in comparison with those of the following Comparison Example 2 which did not have an injection improvement layer and an extraction improvement layer. That is, forming the injection improvement layer and the extraction improvement layer on the drain electrode and the source electrode, respectively, led to reduction in contact resistance even if a transistor was an n-type semiconductor transistor.

### Example 4

### Another Example of Arrangement of Embodiment 1

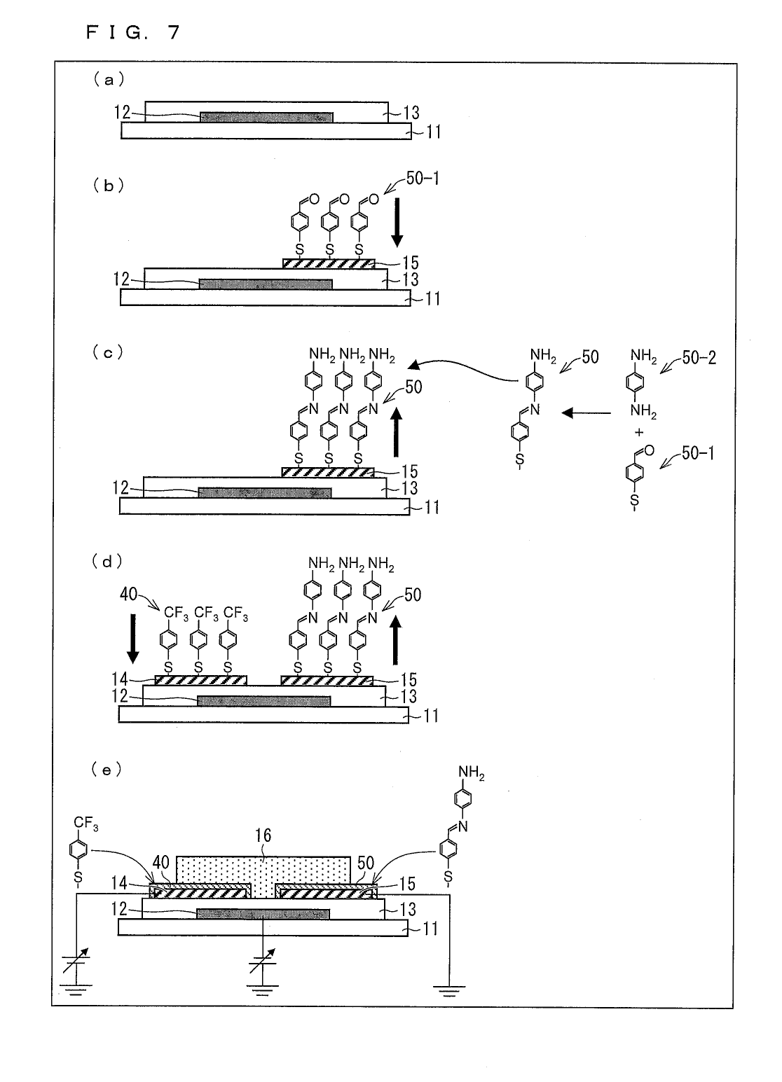

In the present example, an organic transistor was formed on the basis of the method for fabricating the organic transistor illustrated in FIG. 7 and was then evaluated.

First, as illustrated in (a) of FIG. 7, a gate electrode 12 and a gate insulating layer 13, which were made from a same material as Example 2, were formed on a glass substrate 11 under a same condition as Example 2.

Next, as illustrated in (b) of FIG. 7, a drain electrode 15 was made from gold by vacuum depositing via a metal mask so as to have a thickness of 60 nm.

Then, a monomolecular layer, which was made from p-formylbenzenethiolate, was formed as a first monomolecular layer 50-1 on the drain electrode 15. As a specific forming method, the first monomolecular layer 50-1 was formed in such a manner that: 1 mM dehydrated ethanol solution of p-formylbenzenethiolate was prepared; a substrate in which the gate electrode, the gate insulating layer, and also the drain electrode were provided was dipped in the 1 mM dehydrated ethanol solution of p-formylbenzenethiolate for three hours in the 1 mM dehydrated ethanol solution of p-formylbenzenethiolate; and then p-formylbenzenethiolate adhered to the substrate excessively was removed with use of dehydrated ethanol.

Next, as illustrated in (c) of FIG. 7, the extraction improvement layer 50, which was a self-assembled molecular layer, was formed such that 1,4-phenylenediamine serving as a second monomolecular layer 50-2 of the extraction improvement layer was stacked on the first monomolecular layer 50-1 by imine bond. As a specific forming method, the extraction improvement layer 50 is formed such that: 1 mM dehydrated ethanol solution of 1,4-phenylenediamine was prepared; a substrate in which the gate electrode, the gate insulating layer, the drain electrode 15, and also the first monomolecular layer 50-1 were provided was dipped for twelve hours in the 1 mM dehydrated ethanol solution of 1,4-phenylenediamine; and then 1,4-phenylenediamine adhered to the substrate excessively was removed with use of dehydrated ethanol.

Next, as illustrated in (d) of FIG. 7, a source electrode 14 was formed by vacuum depositing gold via a metal mask so as to have a thickness of 60 nm.

Then, a SAM, which was made from p-trifluoro benzene thiol, was formed as an injection improvement layer 40 on the drain electrode 14. As a specific forming method, the injection improvement layer 40 was formed in such a manner that: 1 mM dehydrated ethanol solution of p-trifluoro benzene thiol was prepared; a substrate in which the gate electrode, the gate insulating layer, the drain electrode, and also the source electrode were provided was dipped for three hours in the 1 mM dehydrated ethanol solution of p-trifluoro benzene thiol; and then p-aminobenzenethiol adhered to the substrate excessively was removed with use of dehydrated ethanol.

Next, as illustrated in FIG. 7(e), an organic semiconductor layer 16 was formed by vacuum depositing pentacene via a metal mask so as to have a thickness of 60 nm and to be brought into contact with the injection improvement layer and the extraction improvement layer.

When the organic transistor obtained by means of the method for fabricating the organic transistor was evaluated, the organic transistor has properties of satisfactory values: the mobility of 0.6 cm²/V·s and an ON/OFF ratio of about 10⁶.

Further, a contact resistance between an organic semiconductor and the source electrode and a contact resistance between an organic semiconductor and the drain electrode were evaluated. Then, the contact resistances were reduced to one-fourth in comparison with those of the aforementioned Comparison Example 2 which did not have an injection improvement layer and an extraction improvement layer. That is, forming the injection improvement layer and the extraction improvement layer on the source electrode and on the drain electrode, respectively, led to reduction in contact resistance even if a transistor was an p-type semiconductor transistor.

Note that the present invention is not limited to the description of the embodiments above, and may be modified in numerous ways by a skilled person as long as such modification falls within the scope of the claims. That is, technical means disclosed in different embodiments is appropriately combined with another technical means, another embodiment can be obtained as long as such modification falls within the scope of the claims. The invention being thus described, it will be obvious that the same way may be varied in many ways. Such variations are not to be regarded as a departure from the spirit and scope of the invention, and all such modifications as would be obvious to a skilled person are intended to be included within the scope of the following claims.

### SUMMARY OF THE PRESENT INVENTION

The present invention relates to an organic transistor, and, as described above, includes: a gate electrode; a source electrode; a drain electrode; a gate insulating layer; an organic semiconductor layer provided between the source electrode and the drain electrode; an injection improvement layer provided between the source electrode and the organic semiconductor layer, the injection improvement layer being made from a material or molecules having an electric dipole moment in which a vector directed to a positive pole from a negative pole is directed to the source electrode from the organic semiconductor layer; and an extraction improvement layer provided between the drain electrode and the organic semiconductor layer, the extraction improvement layer being made from a material or molecules having an electric dipole moment in which such a vector is directed to the organic semiconductor layer from the drain electrode, the electric dipole moment of the material or the molecules of the extraction improvement layer having an absolute value being larger than that of the injection improvement layer.

The aforementioned arrangement includes the injection improvement layer provided between the source electrode and the organic semiconductor layer, and the extraction improvement layer provided between the drain electrode and the organic semiconductor layer. Further, the vector of the electric dipole moment of the injection improvement layer is directed to the source electrode from the organic semiconductor layer, meanwhile, the vector of the extraction improvement layer is directed to the organic semiconductor layer from the drain electrode. Therefore, the organic transistor containing a hole as a carrier can reduce (i) the contact resistance between the organic semiconductor layer and the source electrode and (ii) the contact resistance between the organic semiconductor layer and the drain electrode.

Further, the organic transistor does not only include the improvement layers, but also is arranged so that the absolute value of the electric dipole moment of the material or the molecules of the extraction improvement layer is lager than that of the injection improvement layer. Therefore, all holes, which have been injected from the source electrode during operation of the transistor, can be drawn out (extracted) from the organic semiconductor layer to the drain electrode. This makes it possible that reduction in contact resistance leads to reduction in OFF current to thereby prevent reduction in ON/OFF ratio in a case where the transistor is operated two times or more. This can contribute to attain stable transistor operation.

Further, as described above, another organic transistor according to the present invention includes: a gate electrode; a source electrode; a drain electrode; a gate insulating layer; an organic semiconductor layer provided between the source electrode and the drain electrode; an injection improvement layer provided between the source electrode and the organic semiconductor layer, the injection improvement layer being made from a material or molecules having an electric dipole moment in which a vector directed to a positive pole from a negative pole is directed to the organic semiconductor layer from the source electrode; and an extraction improvement layer provided between the drain electrode and the organic semiconductor layer, the extraction improvement layer being made from a material or molecules having an electric dipole moment in which such a vector is directed to the drain electrode from the organic semiconductor layer, the electric dipole moment of the material or the molecules of the extraction improvement layer having an absolute value being larger than that of the injection improvement layer.

The aforementioned arrangement includes the injection improvement layer provided between the source electrode and the organic semiconductor layer, and the extraction improvement layer provided between the drain electrode and the organic semiconductor layer. Further, the vector of the electric dipole moment of the injection improvement layer is directed to the organic semiconductor layer from the source electrode, meanwhile, the vector of the extraction improvement layer is directed to the drain electrode from the organic semiconductor layer. Therefore, the organic transistor containing an electron as a carrier can reduce (i) the contact resistance between the organic semiconductor layer and the source electrode and (ii) the contact resistance between the organic semiconductor layer and the drain electrode.

Further, the organic transistor does not only include the improvement layers, but also is arranged so that the absolute value of the electric dipole moment of the material or the molecules of the extraction improvement layer is lager than that of the injection improvement layer. Therefore, all electrons, which have been injected from the source electrode during operation of the transistor, can be drawn out (extracted) from the organic semiconductor layer to the drain electrode. This makes it possible that reduction in contact resistance leads to reduction in OFF current to thereby prevent reduction in ON/OFF ratio in a case where the transistor is operated two times or more. This can contribute to attain stable transistor operation.

The organic transistor according to the present invention includes the aforementioned arrangement, and in addition, at least one of the injection improvement layer and the extraction improvement layer is preferably the self-assembled monomolecular layer.

According to the aforementioned arrangement, when the at least one of the injection improvement layer and the extraction improvement layer is the self-assembled monomolecular layer (SAM), a thickness of the injection improvement layer or the extraction improvement layer can be reduced to as thin as about a molecule length. This makes it possible to reduce a resistance of the injection improvement layer itself or the extraction improvement layer itself. Further, the SAM has a structure in which single molecules are arrayed. Therefore, by using the SAM, an direction of the electric dipole moment can be easily controlled.

Further, in stead of the aforementioned arrangement, at least one of the injection improvement layer and the extraction improvement layer may be a self-assembled molecular layer.

In the aforementioned arrangement, any one of the injection improvement layer and the extraction improvement layer may be a self-assembled molecular layer (a film including a structure in which the plurality of monomolecular layers are stacked by chemical bonding and a repeating unit of a main chain skeleton). Unlike a case of using only the monomolecular layer, using the self-assembled molecular layer can easily control the film thickness, the direction of the electric dipole moment, and the magnitude thereof.

In addition to the aforementioned arrangement, it is preferable that, in the organic transistor according to the present invention, the injection improvement layer is a layer formed by assembling the organic compounds each represented by the following chemical formula (1):

X-A-Y (1)

(where X is a substituent to be chemically boundable to an atom constituting the source electrode or the drain electrode; A is a main chain skeleton; and Y is an electron withdrawing substituent in a case where a carrier is a hole, and is an electron donating substituent in a case where a carrier is an electron).

Further, in stead of the aforementioned arrangement, in the organic transistor according to the present invention, the extraction improvement layer may be a layer formed by assembling organic compounds each represented by the following chemical formula (1):

X-A-Y (1)

(where X is a substituent to be chemically boundable to an atom constituting the source electrode or the drain electrode; A is a main chain skeleton; and Y is an electron donating substituent in a case where a carrier is a hole, and is an electron withdrawing substituent in a case where a carrier is an electron).

Further, in addition to the aforementioned arrangement, it is preferable that, in the organic transistor according to the present invention, the injection improvement layer is (i) a self-assembled monomolecular layer having the main chain skeleton A in which a molecular skeleton has a H-electron or a a-electron or (ii) a self-assembled molecular layer having the main chain skeleton A in which a plurality of molecular skeletons are connected to one another by chemical bonding.

In addition to the aforementioned arrangement, it is preferable that, in the organic transistor according to the present invention, the extraction improvement layer is (i) a self-assembled molecular layer having the main chain skeleton A in which a monomolecular skeleton has a H-electron or a a-electron or (ii) a self-assembled monomolecular layer having the main chain skeleton A in which a plurality of molecular skeletons are connected to one another by chemical bonding.

Further, it is preferable that, in the organic transistor according to the present invention, the source electrode has a surface facing to the injection improvement layer and being made from gold, and the injection improvement layer is made from a material or molecules having a thiol group; and a gold-thiol bond is formed between the source electrode and the injection improvement layer.

According to the aforementioned arrangement, a gold-thiol bond in which gold and thiol form relatively strong bond is formed between the source electrode and the injection improvement layer. This makes it possible to securely immobilize the injection improvement layer on the source electrode, and to prevent deterioration of the injection improvement layer, which is affected by an electric field generated during driving of the transistor, and in addition to prolong a life of the organic transistor. Further, a distance between a gold atom of a surface of the source electrode and a main chain skeleton of molecules which constitute the injection improvement layer is a distance of a sulfur atom, i.e., short. This makes it possible to reduce a resistance of a connection section for connecting the injection improvement layer and the surface of the source electrode, and further reduce the contact resistance.

Further, it is preferable that, in the organic transistor according to the present invention, the drain electrode has a surface facing to the extraction improvement layer and being made from gold, and the extraction improvement layer is made from a material or molecules having a thiol group; and a gold-thiol bond is formed between the drain electrode and the extraction improvement layer.

According to the aforementioned arrangement, a gold-thiol bond in which gold and thiol form relatively strong bond is formed between the drain electrode and the extraction improvement layer. This makes it possible to securely immobilize the extraction improvement layer on the drain electrode, and to prevent deterioration of the extraction improvement layer, which is affected by an electric field generated during driving of the transistor, and to prolong a life of the organic transistor. Further, a distance between a gold atom of a surface of the drain electrode and a main chain skeleton of molecules which constitute the extraction improvement layer is a distance of a sulfur atom, i.e., short. This makes it possible to reduce a resistance of a connection section for connecting the extraction improvement layer and the surface of the drain electrode, and further reduce the contact resistance.

Further, as described above, an arrangement in which the gold-thiol bond is formed on not only between the drain electrode and the extraction improvement layer but also between the source electrode and the injection improvement layer can further reduce the contact resistance in comparison with an arrangement in which the gold-thiol bond is formed only between the drain electrode and the extraction improvement layer.

Further, it is preferable that, in the organic transistor according to the present invention, the source electrode has a surface having a hydroxyl group, and the material or the molecules of the injection improvement layer includes a silane coupling group or a phosphonic acid moiety; and the source electrode and the injection improvement layer are covalently bound via oxygen between the source electrode and the injection improvement layer.

As described above, if the surface of the source electrode has a hydroxyl group and molecules forming the injection improvement layer has any one of the silane coupling group or the phosphonic acid moiety, a covalent bond of an atom forming the source electrode and a silane coupling agent or a covalent bond of an atom forming the source electrode and an oxygen atom of phosphonic acid is generated between the source electrode and the injection improvement layer. This makes it possible to immobilize the injection improvement layer on the source electrode securely. A covalent bond is generally stronger than a gold-thiol bond. Accordingly, an arrangement having a covalent bond prolongs further life in comparison with an arrangement in which the source electrode and the injection improvement layer are bound by the gold-thiol bond.

Further, it is preferable that, in the organic transistor according to the present invention, the injection improvement layer is a layer formed by assembling organic compounds each represented by the following chemical formula (1):

X-A-Y (1)

(where A is a main chain skeleton is a molecular skeleton having a π-electron; X, which is a substituent, is any one of the thiol group, the silane coupling group, and the phosphonic acid moiety; and Y, which is a substituent, is an electron withdrawing substituent in a case where a carrier is a hole, and Y is an electron donating substituent in a case where a carrier is an electron).

If the injection improvement layer is any one of a SAM and a self-assembled molecular layer, each of which is formed from molecules calculated from the chemical formula (1), and a main chain skeleton A is a molecule skeleton having a π-electron as described above, a resistance of the injection improvement layer itself can be reduced, and this reduction leads to reduction in contact resistance.

Further, it is preferable that, in the organic transistor according to the present invention, the injection improvement layer is a layer made an organic compound represented by the following chemical formula (1):

X-A-Y (1)

(where A is a main chain skeleton is a molecular skeleton having a π-electron; X, which is a substituent, is any one of the thiol group, the silane coupling group, and the phosphonic acid moiety; and Y, which is a substituent, is an electron donating substituent in a case where a carrier is a hole, and Y is an electron withdrawing substituent in a case where a carrier is an electron).

If the extraction improvement layer is any one of a SAM and a self-assembled molecular layer, each of which is formed from molecules calculated from the chemical formula (1), and a main chain skeleton A is a molecule skeleton having a π-electron as described above, a resistance of the extraction improvement layer itself can be reduced, and this reduction leads to reduction in contact resistance.

Further, it is preferable that, in the organic transistor according to the present invention, the drain electrode has a surface having a hydroxyl group, and the material or the molecules of the extraction improvement layer includes a silane coupling group or a phosphonic acid moiety; and the drain electrode and the extraction improvement layer are covalently bound to each other via oxygen between the source electrode and the injection improvement layer.

As described above, if the surface of the drain electrode has a hydroxyl group and molecules forming the extraction improvement layer has any one of the silane coupling group or the phosphonic acid moiety, a covalent bond of an atom forming the drain electrode and a silane coupling agent or a covalent bond of an atom forming the drain electrode and an oxygen atom of phosphonic acid is generated between the drain electrode and the extraction improvement layer. This makes it possible to immobilize the extraction improvement layer on the source electrode securely. A covalent bond is generally stronger than a gold-thiol bond. Accordingly, an arrangement having a covalent bond prolongs further life in comparison with an arrangement in which the drain electrode and the extraction improvement layer are bound by the gold-thiol bond.

Further, as described above, an arrangement in which the covalent bond is formed on not only between the drain electrode and the extraction improvement layer but also between the source electrode and the injection improvement layer can further reduce the contact resistance in comparison with an arrangement in which the covalent bond is formed only between the drain electrode and the extraction improvement layer.

Further, it is preferable that the organic transistor according to the present invention has the injection improvement layer in which the functional group Y is a formyl group or a trifluoromethyl group in a case where a carrier is a hole, and the extraction improvement layer in which the functional group Y of the above chemical formula (1) is a nitro group or a cyano group in a case where a carrier is an electron.

The arrangement, in which the injection improvement layer and the extraction improvement layer have relatively larger absolute values of the electric dipole moments, can highly reduce the contact resistances. This leads to reduction in contact resistance effectively.

Further, a method for fabricating the organic transistor according to the present invention is a method for fabricating an organic transistor having the aforementioned arrangement as described above, the method includes the steps of: (a) forming the source electrode on the gate insulating layer; (b) forming the injection improvement layer on the source electrode; (c) forming the drain electrode on the gate insulating layer on the gate insulating film; (d) forming the extraction improvement layer on the drain electrode; and (e) forming the organic semiconductor layer so as to be brought into contact with the injection improvement layer and the extraction improvement layer after performing the steps (b) and (d).

Further, the organic transistor does not only include the improvement layers, but also is arranged so that the absolute value of the electric dipole moment of the material or the molecules of the extraction improvement layer is lager than that of the injection improvement layer. Therefore, all carriers, which have been injected from the source electrode during operation of the transistor, can be drawn out (extracted) from the organic semiconductor layer to the drain electrode. This makes it possible to reduce the contact resistance generated when the carriers are drawn out to the drain electrode from the organic semiconductor layer. Accordingly, it is possible to provide the organic transistor by which the contact resistances of the whole organic transistor (in which the carriers are transferred from the source electrode to the drain electrode) are reduced. In particular, this makes it possible that reduction in contact resistance leads to reduction in OFF current to thereby prevent reduction in ON/OFF ratio. This can contribute to attain stable transistor operation.

The injection improvement layer and the extraction improvement layer can be individually formed on the source electrode and on the drain electrode, respectively, by forming firstly the source electrode and the injection improvement layer and then forming the drain electrode and the extraction improvement layer or by forming firstly the drain electrode and the extraction improvement layer and then forming the source electrode and the injection improvement layer, even if the source electrode and the drain electrode are made from the same material and the material could be bound to an injection improvement layer material and an extraction improvement layer material.

Further, in another method for fabricating the organic transistor including the aforementioned arrangement according to the present invention as described above, it is preferable that, in the step (b), the injection improvement layer is a self-assembled monomolecular layer or a self-assembled molecular layer in which self-assembled molecular layers are stacked. Further, it is preferable that, in the step (d), the extraction improvement layer is a self-assembled monomolecular layer or a self-assembled molecular multilayer in which self-assembled molecular layers are stacked.

When a method for forming a self-assembled monomolecular layer or a self-assembled multilayer is employed as a method for forming the injection improvement layer and the extraction improvement layer, a layer having an electric dipole moment can be formed in a state of an atmospheric pressure and a low temperature of 150° C. or less. This can reduce deformation of or damage to a thermoplastic plastic substrate.

### INDUSTRIAL APPLICABILITY

The present invention is optimally used as a field effect transistor which is provided in various semiconductor devices, and has a high industrial applicability.

### REFERENCE SIGNS LIST

1 organic transistor

11 substrate

12 gate electrode

13 gate insulating layer

14 source electrode

15 drain electrode

16 organic semiconductor layer

40 injection improvement layer

50 extraction improvement layer

1. An organic transistor comprising:
a gate electrode;
a source electrode;
a drain electrode;
a gate insulating layer;
an organic semiconductor layer which is provided between the source electrode and the drain electrode and whose carriers are holes;
an injection improvement layer for enhancing carrier transfer from the source electrode to the organic semiconductor layer, being provided between the source electrode and the organic semiconductor layer, the injection improvement layer being made from a material or molecules having an electric dipole moment in which a vector directed to a positive pole from a negative pole is directed to the source electrode from the organic semiconductor layer; and
an extraction improvement layer for enhancing carrier transfer from the organic semiconductor layer to the drain electrode, being provided between the drain electrode and the organic semiconductor layer, the extraction improvement layer being made from a material or molecules having an electric dipole moment in which such a vector is directed to the organic semiconductor layer from the drain electrode,
the electric dipole moment of the material or the molecules of the extraction improvement layer having an absolute value being larger than that of the injection improvement layer.

2. An organic transistor comprising:
a gate electrode;
a source electrode;
a drain electrode;
a gate insulating layer;
an organic semiconductor layer which is provided between the source electrode and the drain electrode and whose carriers are electrons;
an injection improvement layer for enhancing carrier transfer from the source electrode to the organic semiconductor layer, being provided between the source electrode and the organic semiconductor layer, the injection improvement layer being made from a material or molecules having an electric dipole moment in which a vector directed to a positive pole from a negative pole is directed to the organic semiconductor layer from the source electrode; and
an extraction improvement layer for enhancing carrier transfer from the source electrode to the organic semiconductor layer, being provided between the drain electrode and the organic semiconductor layer, the extraction improvement layer being made from a material or molecules having an electric dipole moment in which such a vector is directed to the drain electrode from the organic semiconductor layer,
the electric dipole moment of the material or the molecules of the extraction improvement layer having an absolute value being larger than that of the injection improvement layer.

3. The organic transistor according to claim 1, wherein at least one of the injection improvement layer and the extraction improvement layer is a self-assembled monomolecular layer.

4. The organic transistor according to claim 1, wherein at least one of the injection improvement layer and the extraction improvement layer is a self-assembled molecular multilayer in which self-assembled molecular layers are stacked.

5. The organic transistor according to claim 1, Wherein the injection improvement layer is a layer formed by assembling organic compounds each represented by the following chemical formula (1):
X-A-Y (1)
(where X is a substituent to be chemically boundable to an atom constituting the source electrode or the drain electrode; A is a main chain skeleton; and Y is an electron withdrawing substituent).

6. The organic transistor according to claim 1, wherein the extraction improvement layer is a layer formed by assembling organic compounds each represented by the following chemical formula (1):
X-A-Y (1)
(where X is a substituent to be chemically bondable to an atom constituting the source electrode or the drain electrode; A is a main chain skeleton; and Y is an electron donating substituent).

7. The organic transistor according to claim 5, wherein the injection improvement layer is (i) a self-assembled monomolecular layer having the main chain skeleton A in which a molecular skeleton has a π-electron or a σ-electron or (ii) a self-assembled molecular layer having the main chain skeleton A in which a plurality of molecular skeletons are connected to one another by chemical bonding.

8. The organic transistor according to claim 6, wherein the extraction improvement layer is (i) a self-assembled monomolecular layer having the main chain skeleton A in which a molecular skeleton has a π-electron or a σ-electron or (ii) a self-assembled molecular layer having the main chain skeleton A in which a plurality of molecular skeletons are connected to one another by chemical. bonding.

9. The organic transistor according to claim 1, wherein:
the source electrode has a surface which (i) is in contact with the injection improvement layer and (ii) comprises gold, and the injection improvement layer is made from a material or molecules having a thiol group; and
a gold-thiol bond is formed between the source electrode and the injection improvement layer.

10. The organic transistor according to claim 1, wherein:
the drain electrode has a surface which (i) is in contact with the extraction improvement layer and (ii) comprises gold, and the extraction improvement layer is made from a material or molecules having a thiol group; and
a gold-thiol bond is formed between the drain electrode and the extraction improvement layer.

11. The organic transistor according to claim 1, wherein:
the source electrode has a surface having a hydroxyl group, and a material or molecules of the injection improvement layer includes a silane coupling group or a phosphonic acid moiety; and
the source electrode and the injection improvement layer are covalently bound via oxygen between the source electrode and the injection improvement layer.

12. The organic transistor according to claim 1, wherein:
the drain electrode has a surface having a hydroxyl group, and a material or molecules of the extraction improvement layer includes a silane coupling group or a phosphonic acid moiety; and
the drain electrode and the extraction improvement layer are covalently bound via oxygen between the source electrode and the injection improvement layer.

13. The organic transistor according to claim 5, wherein:
the injection improvement layer is such that Y is a formyl group or a trifluoromethyl group;
the extraction improvement layer is such that Y is an amino group or a dimethylamino group.

14-16. (canceled)

17. The organic transistor according to claim 6, wherein:
the injection improvement layer is such that Y is a formyl group or a trifluoromethyl group; and
the extraction improvement layer is such that Y is an amino group or a dimethylamino group.
